(19) United States
(12) Patent Application Publication
(10) Pub. No.: US 2014/0179108 A1
(43) Pub. Date: Jun. 26, 2014

(54) Wafer Edge Protection and Efficiency Using Inert Gas and Ring

(71) Applicant: Applied Materials, Inc., Santa Clara, CA (US)

(72) Inventors: Dung Huu Le, San Jose, CA (US); Graeme Jamieson Scott, Sunnyvale, CA (US); Jivko Dinev, Santa Clara, CA (US); Madhava Rao Yalamanchili, Morgan Hill, CA (US); Khalid Mohiuddin Sirajuddin, San Jose, CA (US); Puneet Bajaj, Mountain View, CA (US); Saravjeet Singh, Santa Clara, CA (US)

(21) Appl. No.: 13/784,591

(22) Filed: Mar. 4, 2013

Related U.S. Application Data
(60) Provisional application No. 61/740,626, filed on Dec. 21, 2012.

(51) Int. Cl. H01L 21/3065; H01L 21/67

(52) U.S. Cl. CPC H01L 21/3065; H01L 21/67069
USPC 438/710; 156/345.33

(57) ABSTRACT

Embodiments of the invention generally relate to an apparatus and method for plasma etching. In one embodiment, the apparatus includes a process ring with an annular step away from an inner wall of the ring and is disposed on a substrate support in a plasma process chamber. A gap is formed between the process ring and a substrate placed on the substrate support. The annular step has an inside surface having a height ranging from about 3 mm to about 6 mm. During operation, an edge-exclusion gas is introduced to flow through the gap and along the inside surface, so the plasma is blocked from entering the space near the edge of the substrate.

### CROSS-REFERENCE TO RELATED APPLICATIONS

This application claims benefit of U.S. Provisional Patent Application Ser. No. 61/740,626, filed Dec. 21, 2012, which is herein incorporated by reference.

### BACKGROUND

1. Field

Embodiments of the invention generally relate to an apparatus and method for plasma etching.

2. Description of the Related Art

For more than half a century, the semiconductor industry has followed Moore's Law, which states that the density of transistors on an integrated circuit doubles about every two years. Continued evolution of the industry along this path will require smaller features patterned onto substrates. In addition, an increasing emphasis is placed on reducing the amount of edge-exclusion on a substrate. Edge-exclusion refers to the area near the edge of a substrate in which no features or devices are formed. Reducing edge-exclusion provides space for forming additional devices nearer the edge of a substrate.

In the manufacturing of the devices, many plasma processes are utilized, such as plasma enhanced chemical vapor deposition (PECVD), physical vapor deposition (PVD), and plasma etching. One type of plasma etching is through silicon via (TSV) etch, which is a process of selectively removing material from a silicon wafer to form a via passing completely through the wafer. As more devices are formed closer to the edge, more vias are formed near the edge of the wafer. The plasma at the edge of the wafer may cause the vias near the edge to slant at an angle with respect to the vertical axis. The tilted vias can create issues such as misalignment with other devices in a 3D integrated circuit (IC) structure. In addition, the plasma may attack the edge of the wafer to cause damage or generate contaminates, which could affect device performance.

Therefore, there is a need for an improved apparatus and method for plasma etching.

### SUMMARY

Embodiments of the invention generally relate to an apparatus and method for plasma etching. In one embodiment, the apparatus includes a process ring having an annular step and is disposed on a substrate support in a plasma process chamber. A gap is formed between the process ring and a substrate placed on the substrate support. The annular step has an inside cylindrical surface having a height ranging from about 3 mm to about 6 mm. During operation, an edge-exclusion gas is introduced to flow through the gap and along the inside cylindrical surface, so the plasma is blocked from entering the space near the edge of the substrate.

In one embodiment, an apparatus for processing a substrate is disclosed. The apparatus comprises a chamber body having a side wall and a bottom wall defining an interior processing region, and a substrate support is disposed in the interior processing region of the chamber body. The substrate support has a radially outward-extending ledge located below an upper surface of the substrate support. The apparatus further comprises a gas supply passage having one or more outlets on the upper surface of the substrate support and a process ring disposed on the ledge of the substrate support. The process ring comprises a ring body having an inner wall and an annular step. The annular step has an inside cylindrical surface having a height between about 3 mm to about 6 mm and a diameter between about 300.1 mm and about 301.00 mm.

In another embodiment, a method for processing a substrate is disclosed. The method comprises placing a substrate on a substrate support within a process chamber and flowing an edge-exclusion gas through a gap defined between a process ring and the substrate. The gap is between about 0.1 mm and about 1.0 mm. The method further comprises confining the edge-exclusion gas flow exiting the gap from flowing radially outward over a distance above a top surface of the substrate. The distance ranges from about 2.2 mm to about 5.2 mm and the edge-exclusion gas flow rate ranges from about 5 sccm to about 15 sccm.

In another embodiment, a method for processing a substrate is disclosed. The method comprises supplying a gas mixture into a process chamber having a substrate disposed therein, and the substrate is disposed over a substrate support. The method further comprises generating a plasma in the process chamber from the gas mixture supplied in the process chamber, and flowing an edge-exclusion gas through a gap defined between the substrate and a process ring disposed on the substrate support. The process ring confines the edge-exclusion gas from flowing radially outward over a distance of at least about 2.2 mm above a top surface of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic cross-sectional view of a process chamber having a process ring according to one embodiment of the invention.

FIG. 2 is an enlarged partial sectional view illustrating a gap defined between a substrate and a conventional process ring.

FIG. 3 is an enlarged partial sectional view illustrating a gap defined between a substrate and the process ring of FIG. 1 according to one embodiment of the invention.

FIG. 4 is a process flow diagram that illustrates a method for etching according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

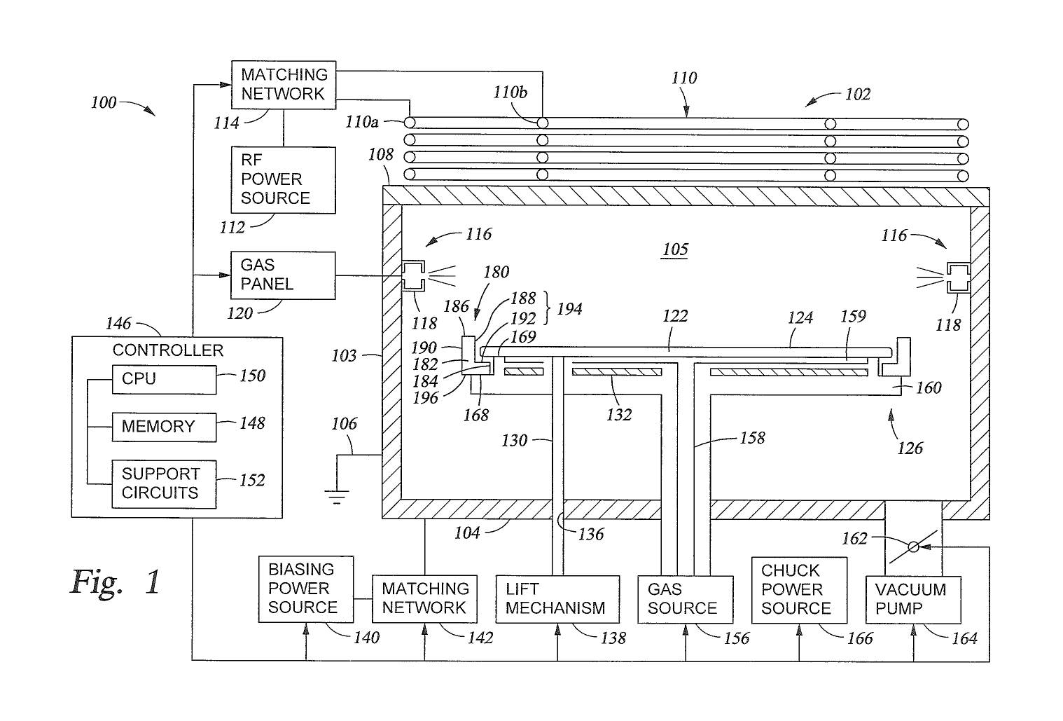

FIG. 1 illustrates a schematic cross-sectional view of a process chamber 100 according to one embodiment of the invention. The process chamber 100 generally includes a chamber body 102 having a bottom wall 104 and side wall 103 defining an interior processing region 105. A substrate support 126 is disposed in the interior processing region 105. The bottom wall 104 and side wall 103 support a substantially flat dielectric ceiling 108. Other embodiments of the process chamber 100 may have other types of ceilings, e.g., a dome-shaped ceiling. Typically, the side wall 103 is formed from a metal, such as aluminum, stainless steel, and the like, and is coupled to an electrical ground 106. An antenna 110 is disposed above the ceiling 108. The antenna 110 comprises one or more inductive coil elements that may be selectively controlled (two co-axial elements 110a and 110b are shown in FIG. 1). The antenna 110 is coupled through a first matching network 114 to an RF power source 112. The RF power source 112 is typically capable of producing up to about 3000 Watts (W) at a tunable frequency in a range from about 100 kHz to about 60 MHz.

A gas panel 120 is coupled to the process chamber 100 to provide process and/or other gases to the interior of the chamber body 102. In the embodiment depicted in FIG. 1, the gas panel 120 is coupled to one or more inlets 116 formed in a channel 118 in the side wall 103 of the chamber body 102. It is contemplated that the one or more inlets 116 may be provided in other locations, for example, in the ceiling 108 of the process chamber 100. The process gases may be an oxygen containing gas, a chlorine containing gas, a fluorine containing gas, an inert gas, or any combination thereof.

The pressure in the process chamber 100 is controlled using a throttle valve 162 and a vacuum pump 164. The vacuum pump 164 and throttle valve 162 are capable of maintaining chamber pressures in the range of about 0.2 to about 20 mTorr.

The substrate support 126 is used to support a substrate 122. The substrate support 126 is coupled through a second matching network 142 to a biasing power source 140. The biasing power source 140 provides biasing power between about 5 to about 500 W at a tunable pulse frequency in the range of about 500 Hz to about 10 kHz. The biasing power source 140 produces pulsed RF power output. Alternatively, the biasing power source 140 may produce pulsed DC power output. It is contemplated that the biasing power source 140 may also provide a constant DC and/or RF power output. The biasing gives the substrate support 126 a positive charge, which attracts the slightly negatively charged plasma, to achieve more anisotropic etch profiles.

In one embodiment, the substrate support 126 includes an electrostatic chuck 160. The electrostatic chuck 160 comprises at least one clamping electrode 132 and is controlled by a chuck power supply 166. In alternative embodiments, the substrate support 126 may comprise substrate retention mechanisms such as a susceptor clamp ring, a vacuum chuck, a mechanical chuck, and the like.

In one embodiment, the electrostatic chuck 160 has a radially outward-extending ledge 168 located below an upper surface 169 of the electrostatic chuck 160, as shown in FIG. 1. The upper surface 169 supports the substrate 122 during processing.

A process ring 180 is disposed on the ledge 168 and circumscribes the upper surface 169. The process ring 180 has a ring body 182 that includes an inner cylindrical wall 184, an outer cylindrical wall 190, an annular step 194, and a top surface 186. The annular step 194 has an inside cylindrical surface 188 and a lower surface 192. The inside cylindrical surface 188 has a diameter greater than that of the inner cylindrical wall 184. In one embodiment, the inside cylindrical surface 188 of the annular step 194 has a diameter between about 300.1 mm and about 301.0 mm. Thus, with a 300 mm diameter substrate, the distance between the edge of the substrate 122 and the inside cylindrical surface 188 is between about 0.1 mm and about 1.0 mm. In one embodiment, the diameter is about 300.5 mm. The diameter of the inside cylindrical surface 188 may vary depending on the diameter of the substrate 122.

The inside cylindrical surface 188 of the annular step 194 has a height between about 3 mm and about 6 mm. A 300 mm substrate generally has a thickness of about 0.8 mm. Thus, the distance between the top surface 186 of the ring body 182 and a top surface 124 of the substrate 122 ranges from about 2.2 mm to about 5.2 mm. In one embodiment, the height of the inside cylindrical surface 188 is about 3.8 mm. As with the diameter, the height of the inside cylindrical surface 188 may also vary depending on the thickness of the substrate 122.

In one embodiment, the inside cylindrical surface 188 of the annular step 194 is perpendicular to a bottom 196 of the ring body 182. In other embodiments, the inside cylindrical surface 188 may be tapered either inwardly or outwardly from the top surface 186.

A lift mechanism 138 is used to lower or raise the substrate 122, onto or off of the substrate support 126. Generally, the lift mechanism 138 comprises a plurality of lift pins (one lift pin 130 is shown) that travel through respective guide holes 136.

An edge-exclusion gas (e.g., helium (He)) from a gas source 156 is provided via a gas conduit 158 to outlets, such as channels 159, formed on the upper surface 169 of the substrate support 126 under the substrate 122. During operation, the edge-exclusion gas is directed to the edge of the substrate 122 to prevent the plasma from attacking the edge and to reduce tilting of the structures etched near the edge.

The controller 146 comprises a central processing unit (CPU) 150, a memory 148, and support circuits 152 for the CPU 150 and facilitates control of the components of the process chamber 100 and, as such, of the etch process, as discussed below in further detail. The controller 146 may be one of any form of general-purpose computer processor that can be used in an industrial setting for controlling various chambers and sub-processors. The memory 148 of the CPU 150 may be one or more of readily available memory such as random access memory (RAM), read only memory (ROM), floppy disk, hard disk, or any other form of digital storage, local or remote. The support circuits 152 are coupled to the CPU 150 for supporting the processor in a conventional manner. These circuits include cache, power supplies, clock circuits, input/output circuitry and subsystems, and the like. The inventive method is generally stored in the memory 148 or other computer-readable medium accessible to the CPU 150 as a software routine. Alternatively, such software routine may also be stored and/or executed by a second CPU (not shown) that is remotely located from the hardware being controlled by the CPU 150.

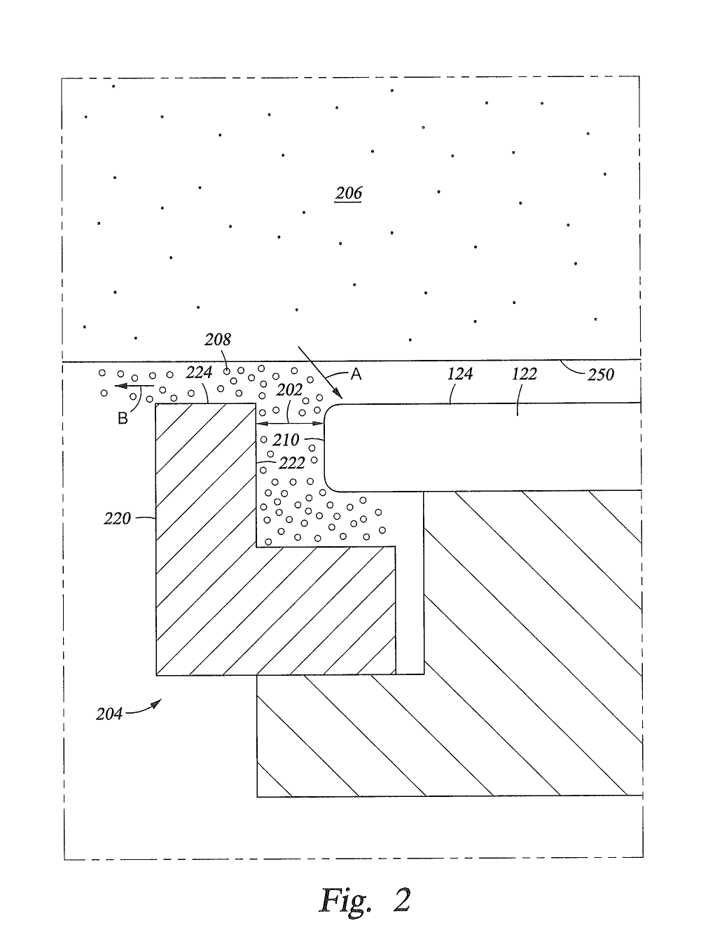

FIG. 2 is an enlarged partial sectional view illustrating a gap 202 defined between the substrate 122 and a conventional process ring 204. As shown in FIG. 2, the conventional process ring 204 has a ring body 220 that includes an inside cylindrical surface 222 and a top surface 224. However, the inside cylindrical surface 222 does not extend substantially above the top surface 124 of the substrate 122, thus, leaving the edge of the substrate 122 unprotected from a plasma 206. The plasma 206 acts as one body and has a boundary 250. The biasing of the substrate 122 attracts etchants, such as ions and radicals, in the plasma 206 towards the substrate 122. Since the plasma 206 extends beyond the outside diameter of the substrate 122, as shown in FIG. 2, etchants from the plasma 206 have a trajectory, as indicated by arrow “A”, that is beyond vertical. The non-vertical trajectory of etchants from the plasma 206 strike the substrate 122 at a non-vertical angle, thereby causes the etched structures to be non-vertical. The plasma 206 may also attack the edge of the substrate 122 to cause cracking or generate contaminants, which could affect device performance.

As shown in FIG. 2, an edge-exclusion gas 208, provided from the gas source, flows through the gas conduit and the channels (not shown) in the substrate support towards the edge of the substrate 122 and through the gap 202 between the conventional process ring 204 and the substrate 122. The edge-exclusion gas 208 may be He or other inert gases. By flowing the edge-exclusion gas 208 out of the gap, the edge of the substrate 122 is protected. Since the top surface 224 of the conventional process ring 204 is relatively close to the top surface 124 of the substrate 122, the edge-exclusion gas 208 escapes between the substrate 122 and the conventional process ring 204 immediately, as indicated by arrow “B”. Thus, the edge of the substrate 122 is only protected at a surface 210 that is immediately adjacent to the inside cylindrical surface 222 of the conventional process ring 204. In addition, because the edge-exclusion gas 208 flows in a radially outward direction, the etchants from the plasma 206 may still strike the substrate 122 at a non-vertical angle, as indicated by arrow “A”, causing structures near the edge of the substrate 122 to be tilted. The tilted structures may cause issues such as misalignment with other devices in a 3D IC structure.

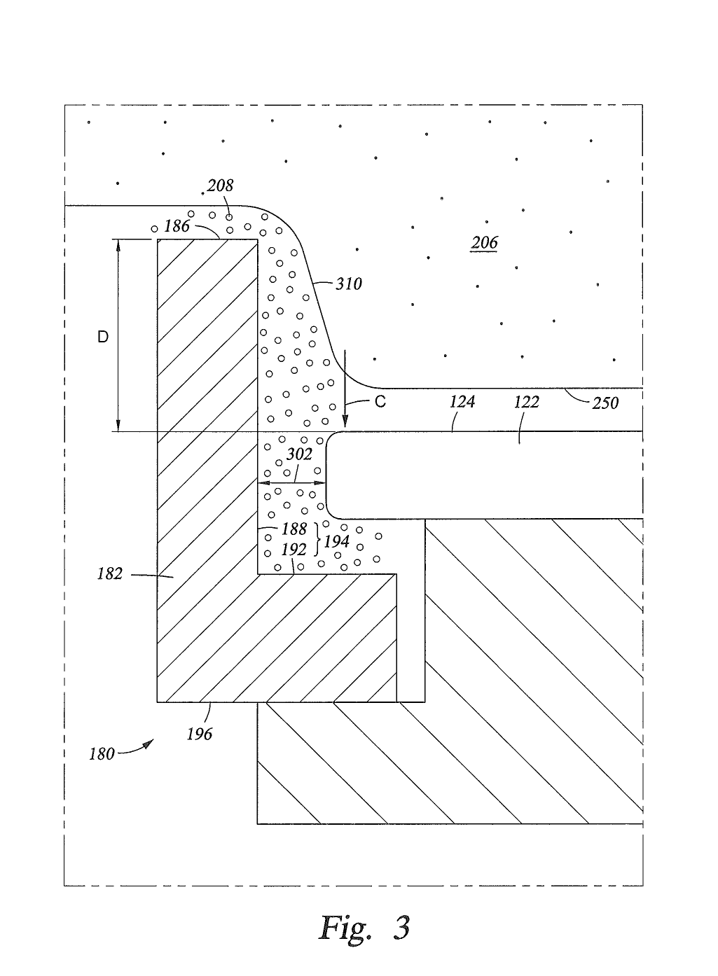

FIG. 3 is an enlarged partial sectional view illustrating a gap 302 defined between the substrate 122 and the process ring 180 of FIG. 1 according to one embodiment of the invention. As shown in FIG. 3, the distance between the top surface 186 and the top surface 124 of the substrate 122 is indicated by “D”. The distance “D” ranges from about 2.2 mm to about 5.2 mm and the inside cylindrical surface 188 has a height ranging from about 3 mm to about 6 mm. In one embodiment, the distance “D” is about 3.0 mm and the height of the inside cylindrical surface 188 is about 3.8 mm. The gap 302 ranges from about 0.1 mm to about 1.0 mm. In one embodiment, the gap 302 is about 0.5 mm.

The relatively tall inside cylindrical surface 188 causes the plasma to move towards the substrate 122 inside of the ring 180, causing a radius 310 to form in the plasma boundary 250 adjacent to and inward of the ring 180. The radius 310 of the plasma boundary 250 forms a void inside the ring 180 above and near the edge of the substrate 122. The edge-exclusion gas 208 is confined in the void circumscribed by the cylindrical surface 188 of the ring 180 and thus protects the edge further into the substrate 122 from the etchants in the plasma 206.

The size of the radius 310 of the plasma boundary 250 affects the trajectory of etchants exiting the plasma and striking the substrate. The size of the radius 310 of the plasma boundary 250 also changes relative to the height of the cylindrical surface 188 of the ring 180. Thus, by selecting an appropriate height for the cylindrical surface 188, the trajectory of etchants exiting the plasma and striking the substrate may be controlled, thereby influencing the verticality of the etched features, such as a via. Due to the biasing of the substrate 122 during etching, the etchants leaving the plasma outward of the substrate have a trajectory that is angled towards the center of the substrate, thus striking the substrate 122 near the edge at an angle that causes the structures etched near the edge to be tapered inwardly from the top surface 124 of the substrate 122. As the inside cylindrical surface 188 gets taller, the radius 310 of the plasma boundary 250 becomes smaller allowing etchants exiting of the plasma 206 to have a more vertical trajectory. This change in trajectory direction compensates the trajectory of the etchants as drawn towards the substrate 122 and in turn causing the structures etched near the edge of the substrate 122 to be less tilted. However, if the inside cylindrical surface 188 exceeds a certain height and the radius 310 become much smaller, the trajectory of the etchants may become directed outwardly relative to vertical, thus causing the structures etched near the edge of the substrate 122 are tapered outwardly from the top surface 124. Thus, proper selection of the height of the inside cylindrical surface 188 allows the etching profile to be controlled to achieve substantially vertical results.

As shown in FIG. 3, the inside cylindrical surface 188 may be perpendicular to the bottom 196 of the ring body 182. In other embodiments, the inside cylindrical surface 188 may be tapered inwardly or outwardly from the top surface 186.

The flow rate of the edge-exclusion gas 208 ranges from about 5 standard cubic centimeters per minute (sccm) to about 15 sccm. In one embodiment, the flow rate of the edge-exclusion gas 208 is about 10 sccm. Because the inside cylindrical surface 188 extends significantly beyond the top surface 124 of the substrate 122, the edge-exclusion gas 208 is confined from flowing radially outward over a distance “D” ranging from about 2.2 mm to about 5.2 mm above the top surface 124 of the substrate 122. In one embodiment, the distance “D” is about 3 mm above the top surface of the substrate 122. The confined edge-exclusion gas 208 along distance “D” only allows the etchants of the plasma 206 to strike the substrate 122 at an angle that is much closer to the vertical axis, as indicated by arrow “C” in FIG. 3, as compared to the conventional process ring 204 depicted in FIG. 2. As a result, the structures, such as vias, formed within 3.0 mm from the edge of the substrate 122 have only less than 1 degree tilt from vertical, and structures beyond 5.0 mm from the edge may exhibit substantially no tilt. The edge of the substrate 122 is also protected from the etchants of the plasma 206.

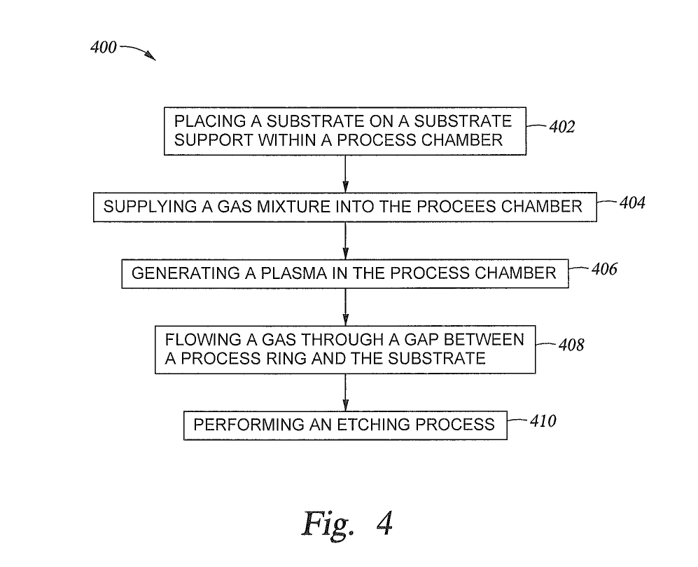

FIG. 4 is a process flow diagram that illustrates a method 400 for etching according to one embodiment of the invention. The method 400 begins at block 402, where a substrate is placed on a substrate support within a process chamber, such as the process chamber 100 shown in FIG. 1 or other suitable etching chamber. In one embodiment, the substrate is a silicon wafer having one or more layers formed thereon, such as the substrate 122 as shown in FIG. 1 or other suitable substrate. In one embodiment, the substrate support is an electrostatic chuck, such as the electrostatic chuck 160 shown in FIG. 1 or other suitable substrate support. The electrostatic chuck may be coupled to a biasing power source to bias the substrate. The power source comprises one or more RF and/or DC power sources.

At block 404, a gas mixture is introduced into the process chamber. The gas mixture may include an oxygen containing gas, a chlorine containing gas, a fluorine containing gas, ammonia, an inert gas, or any combination thereof. In one embodiment, a fluorine containing gas is used. Suitable examples of the fluorine containing gas includes CF₄, CHF₃, CH₂F₂, C₂F₆, C₂F₈, SF₆, NF₃ C₄F₈ and the like. As the fluorine element is an aggressive etchant, the fluorine containing gas supplied in the etching gas mixture is utilized to etch away portions of one or more layers on the substrate.

At block 406, a plasma is generated in the process chamber. After the gas mixture is supplied into the process chamber, an RF power is supplied to form a plasma from the gas mixture therein. The RF source power may be generated from an RF power source, such as the RF power source 112 shown in FIG. 1 or other suitable power source. The RF source power may be supplied to the gas mixture at between about 50 W and about 3000 W and at a frequency between about 100 kHz and about 60 MHz, such as about 13.56 MHz. The plasma may be capacitively coupled to the gas mixture or inductively coupled to the gas mixture. In one embodiment, the plasma is inductively coupled to the gas mixture.

A bias power may also be supplied to the substrate to control of the direction of the plasma generated in the process chamber so as to control vertical trajectory of the ions in the plasma. The bias power may be generated by a biasing power source, such as the biasing power source 140 shown in FIG. 1 or other suitable power source. The bias power may be supplied at between about 5 W and about 500 W. In one embodiment, the RF bias power may be pulsed with a duty cycle between about 10 to about 90 percent at a RF frequency between about 500 Hz and about 10 kHz.

At block 408, an edge-exclusion gas is flowed through a gap defined between a process ring and the substrate. The process ring is the process ring 180 shown in FIG. 1 or other suitable ring for practicing the method 400. The edge-exclusion gas may be a backside gas, a process gas, or an inert gas such as He, and may be generated by a gas source, such as the gas source 156 shown in FIG. 1 or other suitable gas source. The edge-exclusion gas flows from the gas source through a gas conduit to the substrate support, and is directed to the gap by channels formed on an upper surface of the substrate support. The flow rate of the edge-exclusion gas is between about 5 sccm and about 15 sccm. In one embodiment, the flow rate of the edge-exclusion gas is about 10 sccm. The edge-exclusion gas is confined from flowing radially outward over a distance that is between about 2.2 mm and about 5.2 mm above a top surface of the substrate by the process ring. In one embodiment, the process ring confines the edge-exclusion gas from flowing radially outward over a distance of 3.0 mm. The confined edge-exclusion gas prevents the etchants in the plasma from attacking the edge of the substrate and causes the trajectory of the etchants to be substantially vertical, thus forming substantially vertical structures near the edge of the substrate.

At block 410, an etching process is performed to etch the one or more layers disposed on the substrate. The etchants of the plasma etches portions of the one or more layers to form a predetermined pattern. The pattern may be from a mask layer disposed on the one or more layers, and the pattern of the mask layer is transferred to the one or more layers by the etching process. Because of the process ring and the flowing of the edge-exclusion gas, the structures etched near the edge of the substrate are not tilted and the edge of the substrate is protected from the plasma attack.

In summary, a process ring with an annular step having an inside surface extending over a top surface of a substrate is utilized in combination with flowing an edge-exclusion gas to the edge of the substrate to prevent edge attack from a plasma and to reduce tilting of the structures etched near the edge of the substrate.

While the foregoing is directed to embodiments of the present invention, other and further embodiments of the invention may be devised without departing from the basic scope thereof, and the scope thereof is determined by the claims that follow.

What is claimed is:

1. An apparatus for processing a substrate, comprising:
a chamber body having a side wall and a bottom wall defining an interior processing region;
a substrate support disposed in the interior processing region of the chamber body, wherein the substrate support has a radially outward-extending ledge located below an upper surface of the substrate support;
a gas supply passage having one or more outlets on the upper surface of the substrate support; and
a process ring disposed on the ledge of the substrate support, the process ring further comprises:
a ring body having an inner wall and an annular step, wherein the annular step has an inside cylindrical surface having a height between about 3 mm to about 6 mm and a diameter between about 300.1 mm and about 301.0 mm.

2. The apparatus of claim 1, wherein the inside cylindrical surface has a height of about 3.8 mm.

3. The apparatus of claim 1, wherein the inside cylindrical surface has a diameter of about 300.5 mm.

4. The apparatus of claim 1, wherein the inside cylindrical surface is about perpendicular to a bottom of the ring body.

5. The apparatus of claim 1, wherein the inside cylindrical surface is tapered inwardly from a top of the inside cylindrical surface.

6. The apparatus of claim 1, wherein the inside cylindrical surface is tapered outwardly from the top of the inside cylindrical surface.

7. The apparatus of claim 1, wherein a distance between the top of the inside cylindrical surface and a top surface of the substrate ranges from about 2.2 mm to about 5.2 mm.

8. The apparatus of claim 7, wherein the distance between the top of the inside cylindrical surface and the top surface of the substrate is about 3.0 mm.

9. A method for processing a substrate, comprising:
placing a substrate on a substrate support within a process chamber;
flowing an edge-exclusion gas through a gap defined between a process ring and the substrate, wherein the gap is between about 0.1 mm and about 1.0 mm; and
confining the edge-exclusion gas flow exiting the gap from flowing radially outward over a distance above a top surface of the substrate, wherein the distance ranges from about 2.2 mm to about 5.2 mm and the edge-exclusion gas flow rate ranges from about 5 sccm to about 15 sccm.

10. The method of claim 9, wherein the gap is about 0.5 mm.

11. The method of claim 9, wherein the gas flow rate is about 10 sccm.

12. The method of claim 9, wherein confining the gas flow exiting the gap from flowing radially outward over about 3.0 mm above the top surface of the substrate.

13. A method for processing a substrate, comprising:
supplying a gas mixture into a process chamber having a substrate disposed therein, wherein the substrate is disposed over a substrate support;
generating a plasma in the process chamber from the gas mixture supplied in the process chamber; and
flowing an edge-exclusion gas through a gap defined between the substrate and a process ring disposed on the substrate support, wherein the ring confines the edge-exclusion gas from flowing radially outward over a distance of at least about 2.2 mm above a top surface of the substrate.

14. The method of claim 12, wherein the gas mixture comprises a fluorine containing gas.

15. The method of claim 12, wherein the edge-exclusion gas comprises helium.

16. The method of claim 12, wherein the edge-exclusion gas has a flow rate between about 5 sccm and about 15 sccm.

17. The method of claim 16, wherein the flow rate of the edge-exclusion gas is about 10 sccm.

18. The method of claim 12, wherein the ring confining the edge-exclusion gas from flowing radially outward over a distance of about 3.0 mm above the top surface of the substrate.
